(19) United States
(12) Patent Application Publication
(10) Pub. No.: US 2011/0186955 A1
(43) Pub. Date: Aug. 4, 2011

(54) METHOD OF PRODUCING PHOTOELECTRIC CONVERSION DEVICE AND PHOTOELECTRIC CONVERSION DEVICE

(75) Inventors: Tetsuo KAWANO, Ashigarakami-gun (JP); Takashi KOIKE, Ashigarakami-gun (JP)

(73) Assignee: FUJIFILM Corporation, Tokyo (JP)

(21) Appl. No.: 13/011,196

(22) Filed: Jan. 21, 2011

(30) Foreign Application Priority Data
Jan. 29, 2010 (JP) 2010-017658

(51) Int. Cl. H01L 31/032; H01L 31/18

(52) U.S. Cl. 257/463; 438/62; 257/E31.027

(57) ABSTRACT

A method of producing a photoelectric conversion device having a multilayer structure, which includes a lower electrode, a photoelectric conversion layer made of a compound semiconductor layer, a buffer layer made of a compound semiconductor layer, and a transparent conductive layer, formed on a substrate is disclosed. Prior to a buffer layer forming step of forming the buffer layer on the photoelectric conversion layer, Cd ions are diffused into the photoelectric conversion layer by immersing the substrate including the photoelectric conversion layer on the surface thereof in an aqueous solution, which is controlled to a predetermined temperature not less than 40° C. and less than 100° C., contains at least one Cd source and at least one alkaline agent and contains no S ion source, and has a Cd ion concentration of not less than 0.1 M and a pH value in the range from 9 to 13.

### BACKGROUND OF THE INVENTION

1. Field of the Invention

The present invention relates to a method of producing a photoelectric conversion device, such as a solar battery, a CCD device, etc., and also relates to a photoelectric conversion device.

2. Description of the Related Art

Photoelectric conversion devices, which include a photoelectric conversion layer and electrodes electrically connected with the photoelectric conversion layer, are used in applications, such as solar batteries. The main stream of conventional solar batteries has been Si solar batteries, which use bulk single-crystal Si or polycrystal Si, or thin-film amorphous Si. On the other hand, compound semiconductor solar batteries, which do not depend on Si, are now being researched and developed. As the compound semiconductor solar batteries, those of a bulk type, such as GaAs solar batteries, etc., and those of a thin-film type, such as CIS or CIGS solar batteries, which contain a group Ib element, a group IIIb element and a group VIb element, are known. CI(G)S is a compound semiconductor represented by the general formula below:

Cu_{1-z}In₁₋ₓGaₓSe_{2-y}S_{y} (wherein 0≦x≦1, 0≦y≦2, 0≦z≦1)

and it is a CIS semiconductor when x=0 or a CIGS semiconductor when x>0. The CIS and CIGS are collectively described herein as “CI(G) S”.

Conventional thin-film type photoelectric conversion devices, such as CI(G)S photoelectric conversion devices, typically include a buffer layer between the photoelectric conversion layer and a transparent conductive layer (transparent electrode) formed above the photoelectric conversion layer. The buffer layer may be a CdS layer, or a ZnS layer which does not contain Cd, in view of environmental load. The buffer layer serves to achieve (1) prevention of recombination of photogenerated carrier, (2) control of band discontinuity, (3) lattice matching, (4) coverage of surface unevenness of the photoelectric conversion layer, etc. With respect to the CI(G)S photoelectric conversion devices, etc., which have relatively large surface unevenness of the photoelectric conversion layer, film formation may be achieved using CBD (Chemical Bath Deposition), which is a liquid phase process, in order to satisfy the condition (4) above.

Conventionally, it is reported with respect to the case where an n-type buffer layer is formed on the photoelectric conversion layer that energy conversion efficiency of the photoelectric conversion layer is improved by diffusing n-type ions (if the buffer layer is made of CdS, the n-type ions are Cd²⁺, or if the buffer layer is zinc-based, the n-type ions are Zn²⁺) during formation of the n-type buffer layer (the CBD process).

In the case where the buffer layer is formed using the CBD process, however, diffusion of the n-type ions, such as Zn²⁺ or Cd²⁺, and film formation of the buffer layer simultaneously progress. Therefore it is difficult to control both the thickness of the buffer layer and the amount of the diffused n-type ions to be optimal. It is believed that a larger amount of the diffused n-type ions results in a higher photoelectric conversion efficiency, and on the other hand, an excessively large thickness of the buffer layer results in degradation of the photoelectric conversion efficiency.

Japanese Patent No. 4320529 (hereinafter, Patent Document 1) states that, when the buffer layer is formed using the CBD process, diffusion of the Zn or Cd component and the film formation of the ZnS or CdS simultaneously progress, and this tends to cause variation in properties due to the crystal properties and the surface condition of the light-absorbing layer (the photoelectric conversion layer), and proposes a method for achieving optimal diffusion of the n-type dopant (the n-type ions) and optimal formation of the buffer layer at the same time. The method proposed in Patent Document 1 includes, for forming the buffer layer on the photoelectric conversion layer using the CBD process, a first step of diffusing the n-type dopant at an interface of the photoelectric conversion layer, a second step of forming a first buffer layer in a surface reaction rate-limited region, and a third step of forming a second buffer layer on the first buffer layer in a feed rate-limited region, thereby achieving both the optimal diffusion of the n-type dopant and the optimal formation of the buffer layer.

Further, it is taught in M. Bar et al., “Chemical insights into the Cd²⁺/NH₃ treatment-An approach to explain the formation of Cd-compounds on Cu(In,Ga)(S,Se)₂ absorbers”, Solar Energy Materials & Solar cells, Vol. 90, pp. 3151-3157, 2006 (hereinafter, Non-Patent Document 1) that, by forming the buffer layer using a gas-phase process after diffusion of the n-type ions using Cd²⁺/NH₃ has been carried out using a liquid phase process, a higher photoelectric conversion efficiency can be achieved than that in the case where the formation of the buffer layer and the diffusion of the n-type ions are simultaneously carried out using the CBD process.

The method disclosed in Patent Document 1 is aimed to achieve shallow and high-concentration diffusion of the n-type dopant into the photoelectric conversion layer. Specifically, the diffusion is achieved by immersing the photoelectric conversion layer in the reaction solution and heating for 30 minutes (10 to 50 minutes) to raise the temperature from room temperature to 60° C.

However, the present inventors speculated that it is desirable, in view of improvement of the photoelectric conversion efficiency, that the diffusion of the n-type dopant is deeper in the thickness direction of the photoelectric conversion layer, and have studied a method for achieving the deeper diffusion of the n-type dopant in the thickness direction of the photoelectric conversion layer.

As mentioned above, Non-Patent Document 1 states that the photoelectric conversion efficiency can be improved by diffusing the n-type ions using Cd²⁺/NH³. However, this diffusion is carried out at room temperature, and therefore it is unlikely that sufficiently deep diffusion of the n-type ions into the photoelectric conversion layer is achieved.

### SUMMARY OF THE INVENTION

In view of the above-described circumstances, the present invention is directed to providing a method of producing a photoelectric conversion device that is able to achieve deep diffusion of the n-type dopant into the photoelectric conversion layer, and a photoelectric conversion device having high photoelectric conversion efficiency.

An aspect of the method of producing a photoelectric conversion device of the invention is a method of producing a photoelectric conversion device having a multilayer structure formed on a substrate, the multilayer structure including a lower electrode, a photoelectric conversion layer made of a compound semiconductor layer, a buffer layer made of a compound semiconductor layer, and a transparent conductive layer, the method including:

prior to a buffer layer forming step of forming the buffer layer on the photoelectric conversion layer, a diffusion step of diffusing Cd ions into the photoelectric conversion layer, the diffusion step including immersing the substrate including the photoelectric conversion layer on the surface thereof in an aqueous solution controlled to a predetermined temperature not less than 40° C. and less than 100° C., the aqueous solution containing at least one Cd source and at least one alkaline agent and containing no S ion source, and having a Cd ion concentration of not less than 0.1 M and a pH value in the range from 9 to 13.

The unit “M” represents molar concentration (mol/L).

The “S ion source” herein refers to a substance that can form sulfur ions (S²⁻) in an aqueous solution. The S ion source does not include a substance that contains sulfur (S) but does not form S²⁻ in an aqueous solution, such as cadmium sulfide, which forms SO₄²⁻ in an aqueous solution. That is, the solution used in the diffusion step does not contain any material enough to deposit CdS on the photoelectric conversion layer (specifically, a S ion source such as thiourea).

The pH value of the aqueous solution may be in the range from 11.5 to 12.5.

As the Cd source, at least one selected from the group consisting of cadmium sulfide, cadmium acetate, cadmium nitrate, cadmium citrate and hydrates thereof may be used.

As the alkaline agent, a compound containing at least one of NH⁴⁺ ion and Na⁺ ion may be used. In particular, at least one of ammonia and sodium hydroxide may be used.

The buffer layer may be formed using either of a gas phase process or a liquid phase process. In particular, the buffer layer may be formed using a CBD process.

A surface treatment for removing impurities, etc., from the surface of the photoelectric conversion layer may be carried out before or after the diffusion step.

The main component of the photoelectric conversion layer may be at least one compound semiconductor having a chalcopyrite structure. The term “main component” herein refers to a component of not less than 20% by mass.

The main component of the photoelectric conversion layer may be at least one compound semiconductor containing at least one group Ib element selected from the group consisting of Cu and Ag, at least one group IIIb element selected from the group consisting of Al, Ga and In, and at least one group VIb element selected from the group consisting of S, Se, and Te.

The substrate may be an anodized substrate selected from the group consisting of: an anodized substrate provided by forming an anodized film which contains Al₂O₃ as the main component on at least one side of an Al substrate which contains Al as the main component; an anodized substrate provided by forming an anodized film which contains Al₂O₃ as the main component on at least one side of a composite substrate made of a Fe material which contains Fe as the main component and an Al material which contains Al as the main component combined on at least one side of the Fe material; and an anodized substrate provided by forming an anodized film which contains Al₂O₃ as the main component on at least one side of a substrate made of a Fe material which contains Fe as the main component and an Al film which contains Al as the main component formed on at least one side of the Fe material.

In the case where the substrate is a flexible substrate, the surface treatment step, the diffusion step and/or the buffer deposition step may be carried out using a roll-to-roll process. In this case, a feed roll and a take-up roll may be disposed before and after each step, respectively, to carry out each step in a single roll-to-roll process, or a feed roll may be disposed upstream the first step (the surface treatment step or the diffusion step) and a take-up roll may be disposed downstream the last step (the buffer deposition step) to carry out the series of steps in a single roll-to-roll process. Further, one or more additional steps may be inserted between the feed roll and the take-up roll besides the surface treatment step, the diffusion step and the buffer deposition step.

An aspect of the photoelectric conversion device of the invention is a photoelectric conversion device having a multilayer structure formed on a substrate, the multilayer structure including a lower electrode, a photoelectric conversion layer made of a compound semiconductor layer, a buffer layer made of a compound semiconductor layer, and a transparent conductive layer,

wherein a main component of the photoelectric conversion layer is at least one compound semiconductor having a chalcopyrite structure, and

wherein the photoelectric conversion layer contains Cd throughout a film thickness direction thereof, and a concentration of Cd in the film thickness direction decreases from a side of the photoelectric conversion layer facing the buffer layer toward a side of the photoelectric conversion layer facing the lower electrode.

The concentration of Cd in the photoelectric conversion layer at an interface facing the lower electrode may be not less than 0.01 mol %.

This concentration of Cd is a concentration calculated relative to all the elements present in the photoelectric conversion layer.

The photoelectric conversion layer may contain Na.

According to the production method of the invention, prior to the buffer layer forming step of forming the buffer layer on the photoelectric conversion layer, Cd ions are diffused into the photoelectric conversion layer by immersing the substrate having the photoelectric conversion layer on the surface thereof in an aqueous solution, which is controlled to a predetermined temperature not less than 40° C. and less than 100° C., contains at least one Cd source and at least one alkaline agent and contains no S ion source, and has a Cd ion concentration of not less than 0.1 M and a pH value in the range from 9 to 13. In this manner, the Cd ions can be deeply diffused into the photoelectric conversion layer, thereby achieving improvement of the photoelectric conversion efficiency.

The photoelectric conversion device of the invention includes the photoelectric conversion layer which contains Cd ions throughout the film thickness direction thereof, thereby achieving high photoelectric conversion efficiency.

### BRIEF DESCRIPTION OF THE DRAWINGS

FIG. 1 is a schematic sectional view illustrating one example of a photoelectric conversion device, which is produced by a method of producing a photoelectric conversion device of the invention,

FIG. 2 is a diagram illustrating one example of a production apparatus for carrying out the method of producing a photoelectric conversion device of the invention,

FIG. 3 is a diagram illustrating a modified example of the production apparatus for carrying out the method of producing a photoelectric conversion device of the invention, and

FIG. 4 is a schematic sectional view illustrating the structures of examples of a substrate.

### DESCRIPTION OF THE PREFERRED EMBODIMENTS

Hereinafter, the present invention will be described in detail.

First, a typical structure of a photoelectric conversion device, which is produced by a method of producing a photoelectric conversion device of the invention, is described with reference to the drawings.

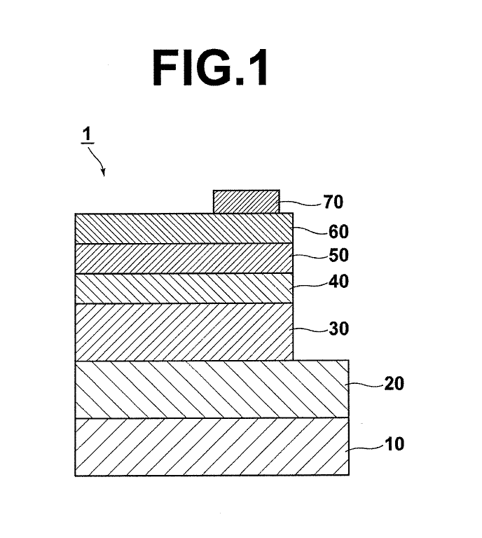

FIG. 1 is a schematic sectional view of the photoelectric conversion device. For ease of visual recognition, elements shown in the drawing are not to scale.

The photoelectric conversion device 1 includes a lower electrode (back electrode) 20, a photoelectric conversion layer 30, a buffer layer 40, a window layer 50, a transparent conductive layer (transparent electrode) 60 and an upper electrode (grid electrode) 70, which are sequentially formed on a substrate 10.

The method of producing a photoelectric conversion device of the invention is to produce a photoelectric conversion device which has a multilayer structure including at least the lower electrode 20, the photoelectric conversion layer 30 made of a compound semiconductor layer, the n-type buffer layer 40 made of a compound semiconductor layer, and the transparent conductive layer 60, formed on the substrate 10, as with the photoelectric conversion device 1 shown in FIG. 1. The method of producing a photoelectric conversion device of the invention includes: prior to a buffer layer forming step of forming the buffer layer 40 on the photoelectric conversion layer 30, a diffusion step of diffusing Cd ions into the photoelectric conversion layer 30, the diffusion step including immersing the substrate 10 including the photoelectric conversion layer 30 on the surface thereof in an aqueous solution controlled to a predetermined temperature not less than 40° C. and less than 100° C., the aqueous solution containing at least one Cd source and at least one alkaline agent and containing no S ion source, and having a Cd ion concentration of not less than 0.1 M and a pH value in the range from 9 to 13.

The Cd ions can efficiently be diffused into the photoelectric conversion layer by carrying out, prior to the buffer deposition step, the diffusion step of diffusing Cd ions into the photoelectric conversion layer in the aqueous solution controlled to a predetermined temperature not less than 40° C. and less than 100° C., containing at least one Cd source and at least one alkaline agent and containing no S ion source, and having a Cd ion concentration of not less than 0.1 M and a pH value in the range from 9 to 13. If the temperature is less than 40° C., rate of diffusion of the Cd ions into the photoelectric conversion layer is too low to achieve a sufficient level of diffusion within a practical treating time, or little or no diffusion occurs. If the temperature exceeds 100° C., water serving as a solvent evaporates. The pH value of the aqueous solution may optionally be in the range from 11.5 to 12.5. The reaction temperature may optionally be in the range from 70 to 95° C. It should be noted that, if a S ion source is contained, CdS will be deposited when the aqueous solution is heated to about 55° C. or more, although it depends on the concentration of a compound forming the S ion source. Since the aqueous solution used in the diffusion step of the invention does not contain any S ion source, no CdS is deposited.

The diffusion distance can be increased by providing a concentration of Cd²⁺ ions in the aqueous solution of not less than 0.1 M before start of the diffusion step.

After the diffusion step, the buffer layer forming step of forming the buffer layer is carried out. According to the invention, the Cd ions (Cd²⁺) can sufficiently be diffused into the photoelectric conversion layer in the diffusion step, and therefore the formation of the buffer layer may be carried out using either of a liquid phase process or a gas phase process, such as MOCVD. In view of further improvement of the photoelectric conversion efficiency, however, a CBD (chemical bath deposition) process may be used to form the buffer layer. The “CBD process” is a method for depositing crystals on a substrate at an appropriate rate in a stable environment by forming a complex of a metal ion M using a reaction solution, which is a metal ion solution having a concentration and a pH value to achieve a supersaturated condition in equilibrium as represented by the following general formula:

[M(L)ᵢ]^{m+} [symbol] Mⁿ⁺+iL

wherein M represents a metal element, L represents a ligand, each of m, n and i represents a positive number.

The reaction solution used to form the buffer layer is, specifically, an aqueous solution containing at least one metal (M) selected from Cd and Zn, a sulfur source, and at least one of ammonia and an ammonium salt. With this, a buffer layer made of CdS, ZnS, Zn(S,O) or Zn(S,O,OH) can be formed.

The sulfur source may be a sulfur-containing compound, such as thiourea (CS(NH₂)₂) or thioacetamide (C₂H₅NS).

If a CdS layer is formed as the buffer layer, the Cd source may be at least one selected from the group consisting of cadmium sulfide, cadmium acetate, cadmium nitrate, cadmium citrate and hydrates thereof. If a Zn(S,O) or ZnS layer is formed as the buffer layer, the Zn source may be at least one selected from the group of Zn sources consisting of zinc sulfide, zinc acetate, zinc nitrate, zinc citrate and hydrates thereof.

The concentration of each component in the reaction solution is not particularly limited, and it may be determined as appropriate depending on the type of the buffer layer.

For example, if the buffer layer is made of CdS, the concentration of Cd may be about 0.00001 to 1 M, the concentration of ammonia or an ammonium salt may be about 0.01 to 5 M, and the concentration of thiourea may be about 0.001 to 1 M.

If the buffer layer is made of Zn(S,O) or Zn(S,O,OH), the concentration of Zn may be about 0.001 to 0.5 M, the concentration of ammonia or an ammonium salt may be about 0.001 to 0.40 M or may optionally be about 0.01 to 0.30 M, and the concentration of thiourea may be about 0.01 to 1.0 M. Further, in this case, the reaction solution may contain a citrate compound (sodium citrate and/or a hydrate thereof). The citrate compound contained in the reaction solution promotes formation of a complex and allows good control of crystal growth in the CBD reaction, thereby allowing stable film formation.

The citrate compound may also be contained in the reaction solution, as necessary, in the case where the buffer layer is CdS-based.

With the production method of the invention, the buffer layer is not deposited in the diffusion step. Further, if the buffer layer is formed using the CBD process, further diffusion of the n-type dopant (the n-type ions) into the photoelectric conversion layer can be achieved at the same time. With respect to the buffer deposition step, if the temperature of the reaction solution is less than 70° C., the reaction rate decreases, and the buffer layer does not grow or, even if the buffer layer grows, it is difficult to provide a desired thickness (for example, 50 nm or more) at a practical reaction rate. On the other hand, if the reaction temperature exceeds 95° C., bubble formation, etc., in the reaction solution increases, and the bubbles, etc., may adhere to the film surface to hinder growth of a flat and uniform film. In addition, if the reaction is carried out with an open system, the concentration, etc., may change due to evaporation of the solvent, etc., and it is difficult to maintain a stable deposition condition of the thin film. Therefore, the buffer deposition step may be carried out at a reaction temperature in the range from 70° C. to 95° C. The reaction temperature may optionally be in the range from 80 to 90° C.

Since the buffer layer is formed after the diffusion step has been carried out, it is not necessary to consider the diffusion of the n-type dopant into the photoelectric conversion layer in the buffer layer forming step. Thus, it is only necessary to consider the conditions of the buffer layer formation, such as the thickness of the buffer layer, thereby allowing easier and accurate thickness control of the buffer layer.

It should be noted that, for further improvement of the photoelectric conversion efficiency, a surface treatment using a KCN solution to remove impurities from the surface of the photoelectric conversion layer 30 may be carried out before or after the diffusion step. The surface treatment using the KCN solution may optionally be carried out before the diffusion step.

In the case where a Zn(S,O) layer is formed as the buffer layer, annealing at a temperature in the range from 150° C. to 220° C. may be carried out for a time in the range from 5 minutes to 90 minutes after the deposition step using the CBD process. This annealing can improve the photoelectric conversion efficiency compared to the case where no annealing is applied.

If the substrate 10 is a flexible substrate, the surface treatment step, the diffusion step and/or the buffer deposition step may be carried out using a so-called roll-to-roll process, which uses a feed roll, on which a long flexible substrate is wound, and a take-up roll, which takes up the substrate after the film formation.

Now, one example of a production apparatus for carrying out the production method according to the embodiment of the invention using the roll-to-roll process is described.

In this example, using a long flexible substrate as the substrate 10, an embodiment of a process including the surface treatment step, the diffusion step of diffusing the n-type dopant into the photoelectric conversion layer and the buffer layer forming step of forming the buffer layer on the photoelectric conversion layer, which are carried out on the substrate 10 having the lower electrode 20 and the photoelectric conversion layer 30 made of a compound semiconductor layer formed thereon, is described.

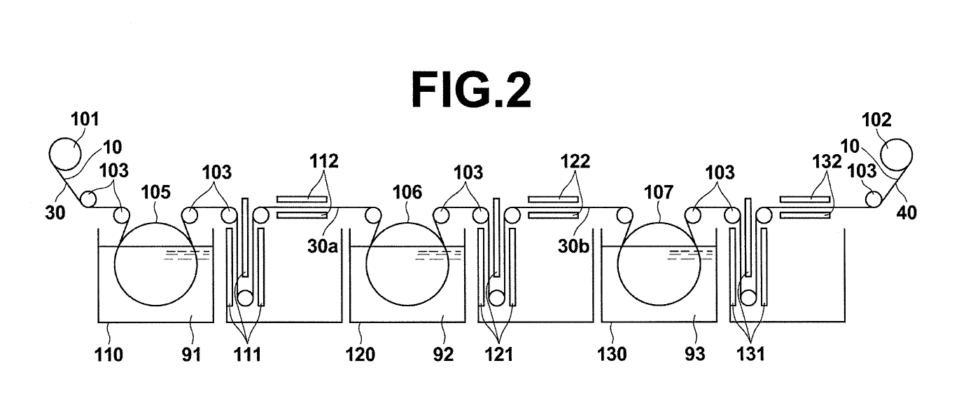

FIG. 2 illustrates the schematic configuration of the production apparatus. The production apparatus includes: a reaction bath 110 for the surface treatment step; a reaction bath 120 for the diffusion step; a reaction bath 130 for the deposition step; and water showers 111, 121 and 131 and hot-air dryers 112, 122 and 132, which are respectively disposed downstream the reaction baths 110, 120 and 130 for washing and drying the substrate after each step. For production using the roll-to-roll process, the production apparatus further includes: a feed roll 101 for feeding the substrate disposed upstream the reaction bath 110 for the surface treatment step; a take-up roll 102 for taking up the substrate having the buffer layer formed thereon disposed downstream the reaction bath 130 for the deposition step; guide rolls 103 for guiding the substrate fed from the feed roll 101 sequentially through the steps of surface treatment, diffusion and deposition; and drums 105, 106 and 107 disposed in the reaction baths 110, 120 and 130, respectively, for immersing each area to be treated of the substrate in each reaction bath.

The substrate 10 having the photoelectric conversion layer formed thereon is wound on the feed roll 101. The substrate 10 is fed from the feed roll 101 to the surface treatment step, and after the buffer layer 40 has been formed on the substrate 10 through the above-described steps, the substrate 10 is taken up on the take-up roll 102.

Each of the reaction baths 120 and 130 includes a temperature controlling means (not shown), which includes a heater, a temperature sensor, etc., so that the temperature of the reaction solution in each reaction bath can be controlled to a desired temperature.

A KCN solution 91 is poured into the reaction bath 110 for the surface treatment step. An aqueous solution 92, which contains at least one Cd source and at least one alkaline agent, contains no S ion source, and has a pH value in the range from 9 to 13, is poured into the reaction bath 120 for the diffusion step. A reaction solution 93, which is an aqueous solution containing an n-type ion source, at least one of ammonia and an ammonium salt, and thiourea, is poured into the reaction bath 130 for the deposition step.

The substrate 10 having the photoelectric conversion layer 30 formed on the surface thereof fed from the feed roll 101 is guided by the guide rolls 103 so that each area to be treated is sequentially treated in each step.

First, the substrate 10 having the photoelectric conversion layer 30 on the surface thereof is immersed in the KCN solution 91 contained in the reaction bath 110 to carry out the surface treatment step of removing impurities from the surface of the photoelectric conversion layer 30.

After the surface treatment step, the substrate 10 having the photoelectric conversion layer 30 on the surface thereof subjected to the surface treatment is washed and dried, and then is immersed in the aqueous solution 92, which is controlled to a predetermined temperature not less than 40° C. and less than 100° C., contained in the reaction bath 120 to diffuse Cd ions into the photoelectric conversion layer 30a. The treating time of the diffusion step may be in the range from 1 minute to 60 minutes. If the treating time is less than 1 minute, it is difficult to achieve a desired amount of the diffused n-type dopant. On the other hand, a treating time exceeding 60 minutes is not practical.

After the diffusion, the substrate 10 having the photoelectric conversion layer 30b on the surface thereof subjected to the diffusion step is washed and dried, and then is immersed in the reaction solution 93, which is controlled to a predetermined temperature in the range from 70° C. to 95° C., contained in the reaction bath 130 to deposit the buffer layer 40 on the photoelectric conversion layer 30b.

Then, the substrate 10 having the buffer layer 40 formed thereon is washed and dried, and is taken up by the take-up roll 102.

The substrate 10 having the buffer layer 40 formed thereon and taken up by the take-up roll 102 is then subjected to steps of forming the window layer, the transparent conductive layer, an extraction electrode, etc., to produce the photoelectric conversion device in the form of a cell.

The treatment carried out in each of the above-described steps is sequentially applied to each area to be treated of the long substrate. Since the components of the reaction solution are scarcely changed by a single diffusion step, the same reaction solution can repeatedly be used in the diffusion step for a plurality of times. On the other hand, in the deposition step, the concentrations of the components in the reaction solution that are deposited as the buffer layer significantly change, and therefore it is necessary to replace the reaction solution for each area to be treated.

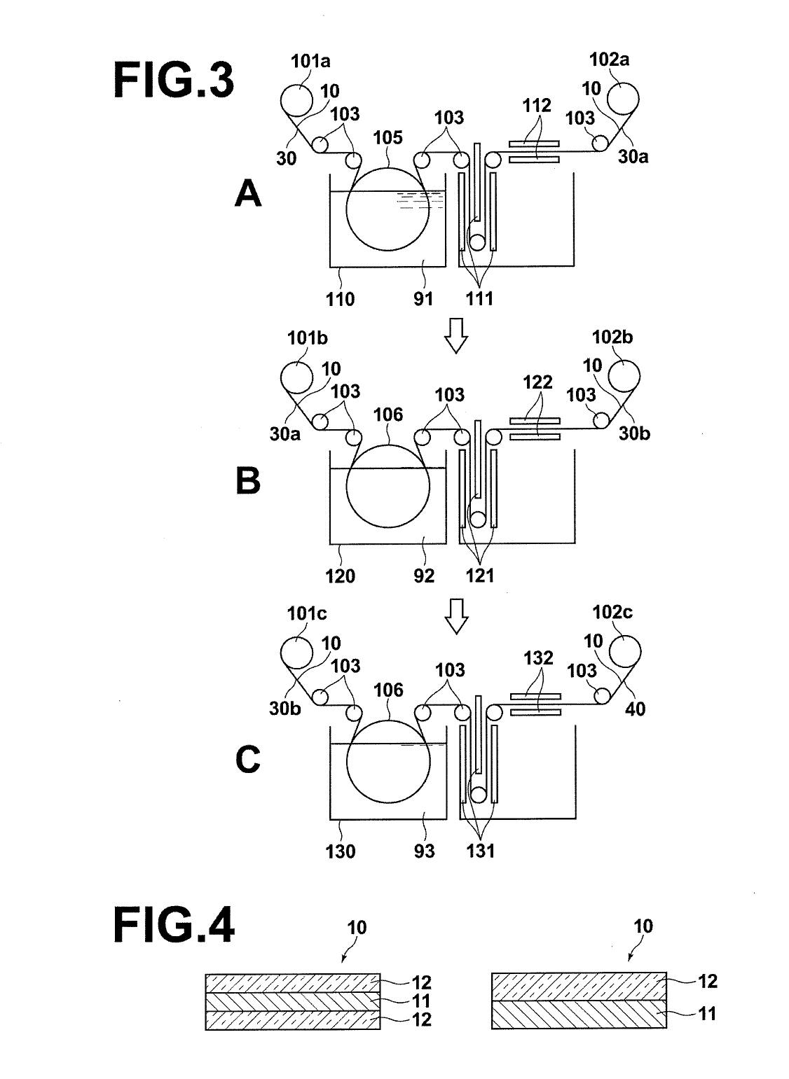

FIG. 3 illustrates a modified example of the production apparatus.

The above-described production apparatus shown in FIG. 2 includes the feed roll and the take-up roll disposed upstream and downstream the three steps, respectively. As shown at A, B and C in FIG. 3, the production apparatus may include feed rolls 101a, 101b and 101c and take-up rolls 102a, 102b and 102c which are disposed upstream and downstream of each step, respectively. In this case, the substrate 10 having the photoelectric conversion layer 30 formed on the surface thereof is taken up by the take-up roll 102a after the surface treatment step shown at A in FIG. 3, and the take-up roll 102a is used as the feed roll 101b for feeding the substrate 10 having the photoelectric conversion layer 30 on the surface thereof subjected to the surface treatment to the diffusion step shown at B in FIG. 3. Similarly, the substrate 10 having the photoelectric conversion layer 30 on the surface thereof subjected to the diffusion step is taken up on the take-up roll 102b after the diffusion step, and the take-up roll 102b is used as the feed roll 101c for feeding the substrate 10 having the photoelectric conversion layer 30 on the surface thereof subjected to the diffusion step to the deposition step shown at C in FIG. 3.

Although the case where the surface treatment, the diffusion and the formation of the buffer layer are achieved using the roll-to-roll process is described above, steps of formation of the other layers, such as the window layer and the transparent electrode layer, may be carried out continuously in a single roll-to-roll process or by using a roll-to-roll process for each step.

Now, details of the individual layers of the photoelectric conversion device 1, which is produced by the production method of the invention, are described.

### Substrate

FIG. 4 is a schematic sectional view of examples of the substrate 10. The substrate 10 is provided by anodizing at least one side of a substrate 11. The substrate 11 may be an Al substrate which contains Al as the main component, a composite substrate made of a Fe material (such as SUS), which contains Fe as the main component, combined with an Al material which contains Al as the main component on at least one side thereof, or a substrate made of a Fe material which contains Fe as the main component, with an Al film which contains Al as the main component formed on at least one side thereof.

The substrate 10 may include anodized films 12 formed on opposite sides of the substrate 11, as shown on the left in FIG. 4, or may include an anodized film 12 formed on one side of the substrate 11, as shown on the right in FIG. 4. The anodized film 12 contains Al₂O₃ as the main component. In view of suppression of warping of the substrate due to a difference of coefficient of thermal expansion between Al and Al₂O₃ and peel-off of the film during a device production process, the substrate 10 including the anodized films 12 formed on the opposite sides of the substrate 11, as shown on the left in FIG. 4, may be used.

The anodization is achieved by immersing the substrate 11, which serves as an anode, with a cathode in an electrolytic solution, and applying a voltage between the anode and the cathode. The surface of the substrate 11 may be subjected to a washing treatment and/or a polishing/smoothing treatment, as necessary, before the anodization. As the cathode, carbon or Al, for example, may be used. The electrolyte is not particularly limited, and an example thereof may be an acidic electrolytic solution that contains one or two or more acids, such as sulfuric acid, phosphoric acid, chromic acid, oxalic acid, sulfamic acid, benzenesulfonic acid and/or amidosulfonic acid.

Anodization conditions depend on the type of the electrolyte used, and are not particularly limited. For example, suitable anodization conditions may be as follows: an electrolyte concentration in the range from 1 to 80% by mass, a solution temperature in the range from 5 to 70° C., an electric current density in the range from 0.005 to 0.60 A/cm², a voltage in the range from 1 to 200 V, and an electrolysis time in the range from 3 to 500 minutes.

Examples of the electrolyte may include sulfuric acid, phosphoric acid, oxalic acid, or a mixture thereof. When such an electrolyte is used, the electrolyte concentration may be in the range from 4 to 30% by mass, the solution temperature may be in the range from 10 to 30° C., the electric current density may be in the range from 0.05 to 0.30 A/cm², and the voltage may be in the range from 30 to 150 V.

The thickness of the substrate 11 and the anodized film 12 are not particularly limited. In view of mechanical strength and thickness and weight reduction of the substrate 10, the thickness of the substrate 11 before anodized may, for example, be in the range from 0.05 to 0.6 mm, or may optionally be in the range from 0.1 to 0.3 mm. In view of insulation, mechanical strength, and thickness and weight reduction of the substrate, the thickness of the anodized film 12 may, for example, be in the range from 0.1 to 100 μm.

Further, the substrate 10 may include a soda-lime glass (SLG) layer on the anodized film 12. The soda-lime glass layer serves to diffuse Na into the photoelectric conversion layer. If the photoelectric conversion layer contains Na, the photoelectric conversion efficiency is further improved.

### Lower Electrode

The main component of the lower electrode (back electrode) 20 is not particularly limited; however, it may be Mo, Cr, W or a combination thereof, in particular, Mo, etc. The thickness of the lower electrode (back electrode) 20 is not particularly limited; however, it may be in the range from about 200 to 1000 nm.

### Photoelectric Conversion Layer

The main component of the photoelectric conversion layer 30 is not particularly limited; however, in view of provision of high photoelectric conversion efficiency, it may be at least one compound semiconductor having a chalcopyrite structure, in particular, at least one compound semiconductor containing a group Ib element, a group IIIb element and a group VIb element.

The main component of the photoelectric conversion layer 30 may be at least one compound semiconductor containing:

at least one group Ib element selected from the group consisting of Cu and A,

at least one group IIIb element selected from the group consisting of Al, Ga and In, and

at least one group VIb element selected from the group consisting of S, Se, and Te.

Examples of the compound semiconductor include

CuAlS₂, CuGaS₂, CuInS₂,

CuAlSe₂, CuGaSe₂,

AgAlS₂, AgGaS₂, AgInS₂,

AgAlSe₂, AgGaSe₂, AgInSe₂,

AgAlTe₂, AgGaTe₂, AgInTe₂,

Cu(In,Al)Se₂, Cu(In,Ga)(S,Se)₂,

Cu_{1-z}In₁₋ₓGaₓSe_{2-y}S_{y} (wherein 0≦x≦1, 0≦y≦2, 0≦z≦1)(CI(G)S),

Ag(In,Ga)Se₂, and Ag(In,Ga)(S,Se)₂.

The thickness of the photoelectric conversion layer 30 is not particularly limited; however, it may be in the range from 1.0 to 3.0 μm, or may optionally be in the range from 1.5 to 2.0 μm.

According to the above-described production method of the invention, the Cd²⁺ ions can efficiently be diffused into the photoelectric conversion layer, and the diffusion distance can be increased from that in the prior art.

In particular, the photoelectric conversion device of the invention is characterized by that the Cd²⁺ ions are diffused throughout the film thickness direction of the photoelectric conversion layer 30. The concentration of Cd in the photoelectric conversion layer 30 is higher at the side facing the buffer layer 40, and decreases toward the side facing the lower electrode 20. In particular, the concentration of Cd may be not less than 0.01 mol % at the interface facing the lower electrode 20. By diffusing Cd throughout the film thickness direction of the photoelectric conversion layer 30, high photoelectric conversion efficiency can be provided. Further, by providing a concentration of Cd of not less than 0.01 mol % at the area having the lowest concentration of Cd, even higher photoelectric conversion efficiency can be achieved.

### Buffer Layer

The buffer layer 40 is an n-type semiconductor, which is made of a layer containing CdS, ZnS, Zn(S,O) or Zn(S,O,OH), in particular, CdS, ZnS or Zn(S,O), as the main component. The thickness of the buffer layer 40 is not particularly limited; however, it may be in the range from 10 nm to 2 μm, or may optionally be in the range from 15 to 200 nm.

### Window Layer

The window layer 50 is an intermediate layer serves to take in light. The composition of the window layer 50 is not particularly limited; however, it may be i-ZnO, etc. The thickness of the window layer 50 is not particularly limited; however, it may be in the range from 10 nm to 2 μm, or may optionally be in the range from 15 to 200 nm. The window layer is optional, i.e., the photoelectric conversion device may not include the window layer 50.

### Transparent Conductive Layer

The transparent conductive layer (transparent electrode) 60 serves to take in light and also serves as an electrode, which forms a pair with the lower electrode 20 and the electric current generated at the photoelectric conversion layer 30 flows therethrough. The composition of the transparent conductive layer 60 is not particularly limited; however, it may be n-ZnO, such as ZnO:Al, etc. The thickness of the transparent conductive layer 60 is not particularly limited; however, it may be in the range from 50 nm to 2 μm.

### Upper Electrode

The main component of the upper electrode 70 is not particularly limited; however, it may be Al, etc. The thickness of the upper electrode 70 is not particularly limited; however, it may be in the range from 0.1 to 3 μm.

The photoelectric conversion device 1 is preferably applicable to solar batteries. A solar battery can be formed by attaching a cover glass, a protective film, etc., to the photoelectric conversion device 1, as necessary.

The photoelectric conversion device produced according to the production method of the invention is applicable not only to solar batteries but also to other applications, such as CCDs.

### EXAMPLES

Devices having the same layer structure as that of the photoelectric conversion device shown in FIG. 1 were produced in different manners as shown in Examples 1 to 5 and Comparative Examples 1 to 5, and photoelectric conversion efficiency of each device was evaluated.

Formation of Part from Substrate to Photoelectric Conversion Layer

A substrate used in each of Examples 1 to 5 and Comparative Examples 1 to 5 was an anodized substrate, which was made of a composite substrate of stainless steel (SUS) and Al provided with an aluminum anodized film (AAO) formed on the Al surface thereof, and was further provided with a soda-lime glass (SLG) layer formed on the surface of the AAO. The thicknesses of the individual layers of the substrate were as follows: the SUS layer had a thickness over 300 μm, the Al layer had a thickness of 300 μm, the AAO layer had a thickness of 20 μm, and the SLG layer had a thickness of 0.2 μm.

A 0.8 μm-thick Mo lower electrode was formed through sputtering on the SLG layer. Then, a 1.8 μm-thick Cu (In_{0.7}Ga_{0.3})Se₂ layer was formed as the photoelectric conversion layer on the Mo lower electrode using a three-stage process, which is known as one of film formation processes to form a CIGS layer.

### Preparation of Reaction Solution 1 for Buffer Layer Formation

A reaction solution 1 (CdSO₄: 0.0001 M, thiourea: 0.10 M, ammonia: 2.0 M) was prepared by mixing predetermined amounts of an aqueous CdSO₄ solution, an aqueous thiourea solution and an aqueous ammonia solution. It should be noted that, in the case where the reaction solution 1 is used, a CdS layer is deposited as the buffer layer.

Preparation of Reaction Solution 2 for buffer layer formation

A reaction solution 2 (ZnSO₄: 0.03 M, thiourea: 0.05 M, sodium citrate: 0.03 M, ammonia: 0.15 M) was prepared by mixing predetermined amounts of an aqueous ZnSO₄ solution, an aqueous thiourea solution and an aqueous ammonia solution. It should be noted that, in the case where the CBD process is carried out using the reaction solution 2, finally a Zn(S,O) layer can be formed as the buffer layer by applying annealing, etc., as necessary.

The diffusion step and the buffer deposition step carried out in each of Examples and Comparative Examples are described below.

It should be noted that the diffusion and the buffer formation were carried out in the following manners of Examples and Comparative Examples after the surface treatment using KCN for removing impurities from the surface of the photoelectric conversion layer was carried out.

### Example 1

Diffusion step: an aqueous solution having a Cd²⁺ ion concentration of 0.1 M and a pH value of 12.0, with addition of ammonia and without addition of NaOH was used as the reaction solution. The substrate having the photoelectric conversion layer formed thereon was immersed for 30 minutes in the aqueous solution controlled to a temperature of 80° C. to diffuse Cd ions into the photoelectric conversion layer.

Buffer layer forming step: the substrate subjected to the diffusion step was immersed for 15 minutes in the reaction bath containing the reaction solution 1 controlled to a temperature of 85° C. to deposit CdS.

### Example 2

Diffusion step: an aqueous solution having a Cd²⁺ ion concentration of 1 M and a pH value of 12.5, with addition of ammonia and without addition of NaOH was used as the reaction solution. The substrate having the photoelectric conversion layer formed thereon was immersed for 30 minutes in the aqueous solution controlled to a temperature of 80° C. to diffuse Cd ions into the photoelectric conversion layer.

Buffer layer forming step: CdS was deposited under the same conditions as in Example 1.

### Example 3

Diffusion step: an aqueous solution having a Cd²⁺ ion concentration of 1 M and a pH value of 12.5, with addition of ammonia and NaOH was used as the reaction solution. The substrate having the photoelectric conversion layer formed thereon was immersed for 30 minutes in the aqueous solution controlled to a temperature of 80° C. to diffuse Cd ions into the photoelectric conversion layer.

Buffer layer forming step: CdS was deposited under the same conditions as in Example 1.

### Example 4

Diffusion step: an aqueous solution having a Cd²⁺ ion concentration of 5 M and a pH value of 12.5, with addition of ammonia and without addition of NaOH was used as the reaction solution. The substrate having the photoelectric conversion layer formed thereon was immersed for 30 minutes in the aqueous solution controlled to a temperature of 80° C. to diffuse Cd ions into the photoelectric conversion layer.

Buffer layer forming step: CdS was deposited under the same conditions as in Example 1.

### Example 5

Diffusion step: an aqueous solution having a Cd²⁺ ion concentration of 5 M and a pH value of 12.5, with addition of ammonia and without addition of NaOH was used as the reaction solution. The substrate having the photoelectric conversion layer formed thereon was immersed for 30 minutes in the aqueous solution controlled to a temperature of 80° C. to diffuse Cd ions into the photoelectric conversion layer.

Buffer layer forming step: The substrate subjected to the diffusion step was immersed for 60 minutes in the reaction solution 2 controlled to a temperature of 90° C., and then was annealed at 200° C. for 60 minutes to form a Zn(S,O) buffer layer.

### Comparative Example 1

No diffusion step was carried out.

Buffer layer forming step: CdS was deposited under the same conditions as in Example 1.

### Comparative Example 2

Diffusion step: an aqueous solution having a Cd²⁺ ion concentration of 0.01 M and a pH value of 12.0, with addition of ammonia and without addition of NaOH was used as the reaction solution. The substrate having the photoelectric conversion layer formed thereon was immersed for 30 minutes in the aqueous solution controlled to a temperature of 80° C. to diffuse Cd ions into the photoelectric conversion layer.

Buffer layer forming step: CdS was deposited under the same conditions as in Example 1.

### Comparative Example 3

Diffusion step: an aqueous solution having a Cd²⁺ ion concentration of 0.1 M and a pH value of 8.5, with addition of ammonia and without addition of NaOH was used as the reaction solution. The substrate having the photoelectric conversion layer formed thereon was immersed for 30 minutes in the aqueous solution controlled to a temperature of 80° C. to diffuse Cd ions into the photoelectric conversion layer.

Buffer layer forming step: CdS was deposited under the same conditions as in Example 1.

### Comparative Example 4

Diffusion step: an aqueous solution having a Cd²⁺ ion concentration of 0.1 M and a pH value of 12.0, with addition of ammonia and without addition of NaOH was used as the reaction solution. The substrate having the photoelectric conversion layer formed thereon was immersed for 30 minutes in the aqueous solution controlled to a temperature of 25° C. to diffuse Cd ions into the photoelectric conversion layer.

Buffer layer forming step: CdS was deposited under the same conditions as in Example 1.

### Comparative Example 5

No diffusion step was carried out.

Buffer layer forming step: a Zn(S,O) buffer layer was formed under the same conditions as in Example 5.

### Production of Solar Batteries

For each of the devices having the buffer layer formed in the manners of Examples 1 to 5 and Comparative Examples 1 to 5, an i-ZnO layer (the window layer) and an n-ZnO layer (the transparent electrode layer) were sequentially formed on the buffer layer, and finally an extraction electrode (the upper electrode) made of Al was formed thereon to produce a single cell solar battery. The thicknesses of the individual layers were as follows: the i-ZnO layer had a thickness of 50 nm, the n-ZnO layer had a thickness of 300 nm, and the Al layer had a thickness of 1 μm.

### Measurement of Conversion Efficiency

For each of the solar batteries produced in the manners of Examples 1 to 5 and Comparative Examples 1 to 5, energy conversion efficiency was measured using light from a solar simulator (Air Mass (AM)=1.5, 100 mW/cm²).

Table 1 shows resulting values of conversion efficiency with details of the diffusion step and the buffer layer forming step of Examples 1 to 5 and Comparative Examples 1 to 5.

The values of the conversion efficiency shown in the table are ratios to a reference value, which is the photoelectric conversion efficiency of the device that was produced by carrying out the buffer layer forming step without carrying out the diffusion step. Since the conversion efficiency depends on the composition of the buffer layer, the values of conversion efficiency of Examples 1 to 4 and Comparative Examples 2 to 4 reference the conversion efficiency of Comparative Example 1, and the value of conversion efficiency of Example 5 references the conversion efficiency of Comparative Example 5.

TABLE 1

| | | | | | | | Comp. | Comp. | Comp. | Comp. | Comp. |
|---|---|---|---|---|---|---|---|---|---|---|---|
| | | Example 1 | Example 2 | Example 3 | Example 4 | Example 5 | Example 1 | Example 2 | Example 3 | Example 4 | Example 5 |
| Conditions | Concentration | 0.1 | 1 | 1 | 5 | 5 | No | 0.01 | 0.1 | 0.1 | No |
| of Reaction | of Cd²⁺ ion | | | | | | Diffusion | | | | Diffusion |
| Solution in | pH | 12.0 | 12.5 | 12.5 | 12.5 | 12.5 | Step | 12.0 | 8.5 | 12.0 | Step |
| Diffusion | Treatment | 80° C. | 80° C. | 80° C. | 80° C. | 80° C. | | 80° C. | 80° C. | 25° C. | |
| Step | Temperature | | | | | | | | | | |
| | Addition of | With | With | With | With | With | | With | With | With | |
| | Ammonia | | | | | | | | | | |
| | Addition of | Without | Without | With | Without | Without | | Without | Without | Without | |
| | NaOH | | | | | | | | | | |
| Buffer | Buffer Layer | CdS | CdS | CdS | CdS | Zn(S,O) | CdS | CdS | CdS | CdS | Zn(S,O) |
| Layer | Treatment | 85° C. | 85° C. | 85° C. | 85° C. | 90° C. | 85° C. | 85° C. | 85° C. | 85° C. | 90° C. |
| Forming | Temperature | | | | | | | | | | |
| Step | Treating time | 15 | 15 | 15 | 15 | 60 | 15 | 15 | 15 | 15 | 60 |
| | | minutes | minutes | minutes | minutes | minutes | minutes | minutes | minutes | minutes | minutes |
| Conversion | Ratio to | +1.4% | +2.2% | +2.4& | +3.1% | — | Reference | +0.4% | +0.1% | +0.3% | — |
| Efficiency | Reference 1 | | | | | | 1 | | | | |
| in the Form | Ratio to | — | — | — | — | +1.8% | — | — | — | — | Reference |
| of Cell | Reference 2 | | | | | | | | | | 2 |
| (Ratio to | | | | | | | | | | | |
| Reference) | | | | | | | | | | | |

As shown in Table 1, the solar batteries which were produced by carrying out the deposition of the CdS buffer layer after the diffusion step under the conditions of Examples 1 to 4 had a conversion efficiency greater by 0.6% or more than that of the solar battery which was produced by carrying out the deposition of CdS without carrying out the diffusion step (Comparative Example 1). It has been found that a larger Cd²⁺ ion concentration tends to provide a higher conversion efficiency.

The solar battery of Comparative Examples 2 to 4 had a higher conversion efficiency than that of the solar battery of Comparative Example 1, which was produced by carrying out the deposition of CdS without carrying out the diffusion step. However, it is believed that sufficient diffusion was not achieved because of the low Cd ion concentration, the low pH value or the low treatment temperature.

Further, the solar battery which was produced by carrying out the formation of the Zn(S,O) buffer layer after the diffusion step under the conditions of Example 5 had an improved conversion efficiency (improved by 1.8%) compared to the conversion efficiency of the solar battery which was produced by forming the Zn(S,O) buffer layer without carrying out the diffusion step (Comparative Example 5).

It should be noted that the present inventors estimate that the improvement of the conversion efficiency in each Example is associated with the increase of the diffusion distance of the Cd ions in the photoelectric conversion layer.

What is claimed is:

1. A method of producing a photoelectric conversion device having a multilayer structure formed on a substrate, the multilayer structure including a lower electrode, a photoelectric conversion layer made of a compound semiconductor layer, a buffer layer made of a compound semiconductor layer, and a transparent conductive layer, the method comprising:
prior to a buffer layer forming step of forming the buffer layer on the photoelectric conversion layer, a diffusion step of diffusing Cd ions into the photoelectric conversion layer, the diffusion step comprising immersing the substrate including the photoelectric conversion layer on the surface thereof in an aqueous solution controlled to a predetermined temperature not less than 40° C. and less than 100° C., the aqueous solution containing at least one Cd source and at least one alkaline agent and containing no S ion source, and having a Cd ion concentration of not less than 0.1 M and a pH value in the range from 9 to 13.

2. The method as claimed in claim 1, wherein the aqueous solution has a pH value in the range from 11.5 to 12.5.

3. The method as claimed in claim 1, wherein the Cd source comprises at least one selected from the group consisting of cadmium sulfide, cadmium acetate, cadmium nitrate, cadmium citrate and hydrates thereof.

4. The method as claimed in claim 1, wherein the alkaline agent comprises a compound containing at least one of NH₄⁺ ion and Na⁺ ion.

5. The method as claimed in claim 4, wherein the alkaline agent comprises at least one of ammonia and sodium hydroxide.

6. The method as claimed in claim 1, wherein the buffer layer is formed using a CBD process.

7. The method as claimed in claim 1, further comprising a surface treatment step of removing impurities from a surface of the photoelectric conversion layer before or after the diffusion step.

8. The method as claimed in claim 1, wherein a main component of the photoelectric conversion layer is at least one compound semiconductor having a chalcopyrite structure.

9. The method as claimed in claim 8, wherein the main component of the photoelectric conversion layer is at least one compound semiconductor containing
at least one group Ib element selected from the group consisting of Cu and Ag,
at least one group IIIb element selected from the group consisting of Al, Ga and In, and
at least one group VIb element selected from the group consisting of S, Se, and Te.

10. The method as claimed in claim 1, wherein the substrate comprises an anodized substrate selected from the group consisting of:
an anodized substrate provided by forming an anodized film which contains Al₂O₃ as the main component on at least one side of an Al substrate which contains Al as the main component;
an anodized substrate provided by forming an anodized film which contains Al₂O₃ as the main component on at least one side of a composite substrate made of a Fe material which contains Fe as the main component and an Al material which contains Al as the main component combined on at least one side of the Fe material; and
an anodized substrate provided by forming an anodized film which contains Al₂O₃ as the main component on at least one side of a substrate made of a Fe material which contains Fe as the main component and an Al film which contains Al as the main component formed on at least one side of the Fe material.

11. The method as claimed in claim 1, wherein
the substrate is a flexible substrate, and
the diffusion step and/or the buffer layer forming step are carried out using a roll-to-roll process.

12. A photoelectric conversion device having a multilayer structure formed on a substrate, the multilayer structure including a lower electrode, a photoelectric conversion layer made of a compound semiconductor layer, a buffer layer made of a compound semiconductor layer, and a transparent conductive layer,
wherein a main component of the photoelectric conversion layer comprises at least one compound semiconductor having a chalcopyrite structure, and
wherein the photoelectric conversion layer contains Cd throughout a film thickness direction thereof, and a concentration of Cd in the film thickness direction decreases from a side of the photoelectric conversion layer facing the buffer layer toward a side of the photoelectric conversion layer facing the lower electrode.

13. The photoelectric conversion device as claimed in claim 12, wherein the concentration of Cd in the photoelectric conversion layer at an interface facing the lower electrode is not less than 0.01 mol %.

14. The photoelectric conversion device as claimed in claim 12, wherein the photoelectric conversion layer contains Na.
